(19) United States
(12) Patent Application Publication
(10) Pub. No.: US 2024/0297196 A1
(43) Pub. Date: Sep. 5, 2024

(54) SEMICONDUCTOR DEVICE AND IMAGING DEVICE

(71) Applicant: SONY SEMICONDUCTOR SOLUTIONS CORPORATION, Kanagawa (JP)

(72) Inventor: Yuriko YAMANO, Kanagawa (JP)

(73) Assignee: SONY SEMICONDUCTOR SOLUTIONS CORPORATION, Kanagawa (JP)

(21) Appl. No.: 18/550,281

(22) PCT Filed: Jan. 21, 2022
(86) PCT No.: PCT/JP2022/002109

§ 371 Date: Sep. 12, 2023

(30) Foreign Application Priority Data
Mar. 24, 2021 (JP) 2021-049544

(51) Int. Cl. H01L 27/146; H01L 25/065

(52) U.S. Cl. CPC H01L 27/14636; H01L 25/0657; H01L 27/14618; H01L 2225/0651

(57) ABSTRACT

The present technology relates to a semiconductor device and an imaging device capable of preventing the film thickness of wiring from becoming uneven. The semiconductor device includes: a substrate; a wiring layer on a first surface of the substrate; a first wiring provided on a second surface opposite the first surface of the substrate; and a through electrode that connects a second wiring in the wiring layer and the first wiring and penetrates the substrate, in which a part of the first wiring has a region in an uneven shape. The uneven shape is a non-through hole that does not penetrate the substrate. The present technology can be applied to, for example, a semiconductor device having a structure in which a plurality of chips is stacked and wiring layers are connected to each other.

### TECHNICAL FIELD

The present technology relates to a semiconductor device and an imaging device, and for example, relates to a semiconductor device and an imaging device in which a film thickness of wiring formed on a substrate surface is adjusted to be uniform.

### BACKGROUND ART

For example, back-illuminated solid-state imaging elements, in which the back surface side of the semiconductor substrate is a light incident surface, are widely used. It has been proposed to make such a back-illuminated solid-state imaging element into a single chip by joining, for example, the first semiconductor element that performs signal processing and the second semiconductor element that is a back-illuminated solid-state imaging element so that their respective wiring layers face each other (see, for example, Patent Document 1).

### CITATION LIST

### Patent Document

Patent Document 1: Japanese Patent Application Laid-Open No. 2010-245506

### SUMMARY OF THE INVENTION

### Problems to be Solved by the Invention

In some of the solid-state imaging elements described above, wiring to extract signals from the wiring layer is formed, for example, on the substrate of the first semiconductor element by an electrolytic plating method. In this wiring, for example, there is a possibility that a region where the wiring becomes dense and a region where the wiring becomes sparse are mixed due to a limitation of a layout of the wiring or the like. When the density difference is generated in the wiring, the density difference is generated in the density of the line of electric force during plating.

In a region where the wiring density is sparse, the wiring height becomes high (the film thickness becomes thick) because the electric field is concentrated, and in a region where the wiring density is dense, the wiring height becomes low (the film thickness becomes thin) because the electric field is dispersed. In a case where such a variation in the height (film thickness) of the wiring is large, it is necessary to perform packaging so as to complement the difference in the wiring height in a subsequent process, and there is a possibility that the thickness of the package increases. Therefore, it is desired that wiring height variation is prevented as much as possible.

The present technology has been made in view of such a situation, and is intended to prevent a difference from occurring in the height of the wiring.

### SOLUTIONS TO PROBLEMS

A semiconductor device according to one aspect of the present technology is a semiconductor device including: a substrate; a wiring layer on a first surface of the substrate; a first wiring provided on a second surface opposite the first surface of the substrate; and a through electrode that connects a second wiring in the wiring layer and the first wiring and penetrates the substrate, in which a part of the first wiring has a region in an uneven shape.

An imaging device according to one aspect of the present technology is an imaging device including: a first chip on which a solid-state imaging element is formed; and a second chip that processes a signal from the first chip, the second chip including: a substrate; a wiring layer on a first surface of the substrate; a first wiring provided on a second surface opposite the first surface of the substrate; and a through electrode that connects a second wiring in the wiring layer and the first wiring and penetrates the substrate, in which a part of the first wiring has a region in an uneven shape.

A semiconductor device according to one aspect of the present technology includes: a substrate; a wiring layer on a first surface of the substrate; a first wiring provided on a second surface opposite the first surface of the substrate; and a through electrode that connects a second wiring in the wiring layer and the first wiring and penetrates the substrate, in which a part of the first wiring has a region in an uneven shape.

An imaging device according to one aspect of the present technology includes a first chip on which a solid-state imaging element is formed, and a second chip that processes a signal from the first chip. The second chip includes the semiconductor device.

Note that the imaging device may be an independent device or an internal block constituting one device.

### BRIEF DESCRIPTION OF DRAWINGS

FIG. 1 is a diagram illustrating a configuration example of an embodiment of a semiconductor device to which the present technology is applied.

FIG. 2 is a cross-sectional view illustrating a configuration example of a semiconductor device according to a first embodiment.

FIG. 3 is a diagram for explaining determination of wiring density.

FIG. 4 is a diagram for explaining manufacturing of the semiconductor device.

FIG. 5 is a diagram for explaining manufacturing of the semiconductor device.

FIG. 6 is a cross-sectional view illustrating a configuration example of a semiconductor device according to a second embodiment.

FIG. 7 is a diagram for explaining manufacturing of the semiconductor device.

FIG. 8 is a diagram for explaining manufacturing of the semiconductor device.

FIG. 9 is a cross-sectional view illustrating a configuration example of a semiconductor device according to a third embodiment.

FIG. 10 is a cross-sectional view illustrating a configuration example of a semiconductor device according to a fourth embodiment.

FIG. 11 is a cross-sectional view illustrating a configuration example of a semiconductor device according to a fifth embodiment.

FIG. 12 is a cross-sectional view illustrating a configuration example of a semiconductor device according to a sixth embodiment.

FIG. 13 is a cross-sectional view illustrating a configuration example of a semiconductor device according to a seventh embodiment.

FIG. 14 is a diagram for explaining manufacturing of the semiconductor device.

FIG. 15 is a diagram for explaining manufacturing of the semiconductor device.

FIG. 16 is a cross-sectional view illustrating a configuration example of a semiconductor device according to an eighth embodiment.

FIG. 17 is a cross-sectional view illustrating a configuration example of a semiconductor device according to a ninth embodiment.

FIG. 18 is a cross-sectional view illustrating a configuration example of a semiconductor device according to a 10th embodiment.

FIG. 19 is a cross-sectional view illustrating a configuration example of a semiconductor device according to an 11th embodiment.

FIG. 20 is a diagram for explaining manufacturing of the semiconductor device.

FIG. 21 is a diagram illustrating an example of an electronic device.

FIG. 22 is a view depicting an example of a schematic configuration of an endoscopic surgery system.

FIG. 23 is a block diagram depicting an example of a functional configuration of a camera head and a camera control unit (CCU).

FIG. 24 is a block diagram illustrating an example of a schematic configuration of a vehicle control system.

FIG. 25 is an illustrative view illustrating an example of an installation position of an outside-vehicle information detecting section and an imaging section.

### MODE FOR CARRYING OUT THE INVENTION

Hereinafter, modes (hereinafter, referred to as embodiments) for implementing the present technology will be described.

### First Embodiment

The present technology described below is applicable to a semiconductor device including a chip of an imaging element such as a charged-coupled device (CCD) or a complementary metal-oxide semiconductor (CMOS). The present technology is also applicable to a semiconductor device including a chip of an optical element such as a light receiving element such as photo diode (PD), micro electro mechanical system (MEMS) elements such as optical switches and mirror devices, a light emitting element such as a laser diode (LD), a light emitting diode (LED), and a vertical cavity surface emitting laser (VCSEL).

The present technology is also applicable to a semiconductor device including a processing circuit that processes a signal from the semiconductor device described above. The present technology is also applicable to a semiconductor device having a laminated structure in which wiring layers of semiconductor devices are connected to each other.

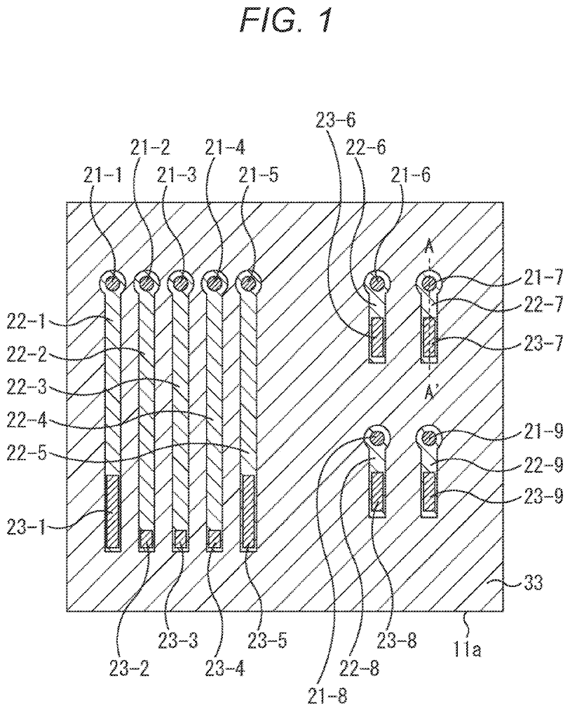

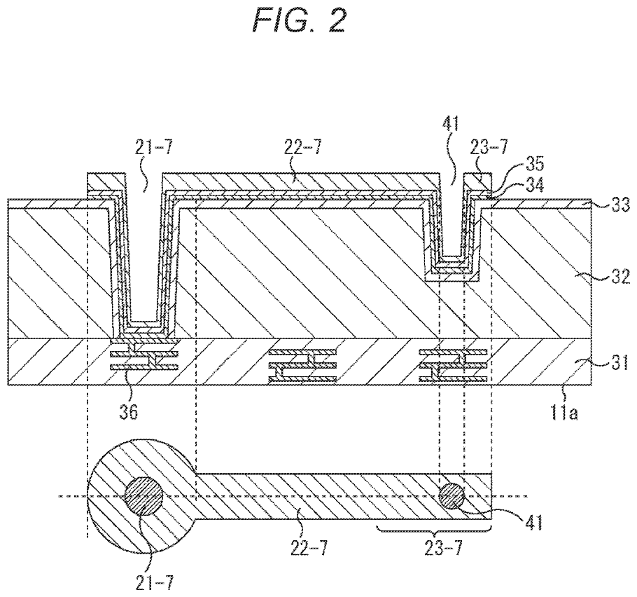

FIG. 1 is a plan view illustrating a configuration example of a semiconductor device 11a according to a first embodiment. FIG. 2 is a cross-sectional view illustrating a configuration example of the semiconductor device 11a along a line A-A′ in the upper part of FIG. 1.

As illustrated in FIG. 2, the semiconductor device 11a includes a silicon substrate 32 on a wiring layer 31, and an insulating film 33 formed on the silicon substrate 32. A redistribution layer 22-7 is provided on the insulating film 33. As illustrated in FIG. 1, the redistribution layer 22-7 is formed on the surface (hereinafter, described as an upper surface) on which the insulating film 33 is formed.

FIG. 1 is a diagram illustrating a configuration example of a part of an upper surface of the semiconductor device 11a, and redistribution layers 22-1 to 22-9 are formed in a part of the semiconductor device 11a. The redistribution layers 22-1 to 22-5 are formed in a left region in the drawing, the redistribution layers 22-6 and 22-7 are formed in an upper right region in the drawing, and the redistribution layers 22-8 and 22-9 are formed in a lower right region in the drawing. Hereinafter, the redistribution layers 22-1 to 22-9 will be simply referred to as the redistribution layer 22 in a case where it is not necessary to distinguish the redistribution layers from each other. Other parts are described in a similar manner.

One end of the redistribution layer 22 is connected to a through electrode 21, and the other end is provided with a recess-protrusion formation region 23. For example, a through electrode 21-1 is connected to one end of the redistribution layer 22-1, and a recess-protrusion formation region 23-1 is provided at the other end.

A through electrode 21-7 is connected to one end of the redistribution layer 22-7, and the through electrode 21-7 is connected to wiring 36 provided in the wiring layer 31 in a case of being viewed in the cross-sectional view as illustrated in FIG. 2. The other through electrodes 21 are also electrically connected to the wiring layer 31. The redistribution layer 22 is constituted by, for example, copper (Cu) as a material.

The through electrode 21-7 is formed by stacking the insulating film 33, a barrier metal film 34, and a seed film 35 on the side surface of the through hole. The through electrode 21-7 is formed integrally with the redistribution layer 22-7. As a material of the insulating film 33, an inorganic film such as SiO2, SiN, SiON, or a low-k film can be used. As the material of the barrier metal film 34, tantalum (Ta), titanium (Ti), tungsten (W), zirconium (Zr), a nitride film thereof, a carbonized film thereof, and the like can be used.

In the redistribution layer 22-7, a recess-protrusion formation region 23-7 is formed. In the example illustrated in FIG. 2, a non-through hole 41 having a similar configuration to the through electrode 21-7 is formed in the recess-protrusion formation region 23-7. In the example illustrated in FIG. 2, one non-through hole 41 is formed. The non-through hole 41 is provided to reduce the influence of the density difference of the wiring density of the redistribution layer 22.

Sparseness/denseness of the wiring density of the redistribution layer 22 will be described. Note that, in the case of considering sparseness/denseness of wiring density, the redistribution layer 22 will be described, but the description will be continued assuming that the redistribution layer 22 includes the through electrode 21 and the recess-protrusion formation region 23 (the non-through holes 41 formed in the recess-protrusion formation region 23).

The redistribution layer 22 arranged on the upper surface of the semiconductor device 11a has layout restrictions, and the redistribution layer 22 may not be arranged on the entire upper surface in some cases. On the upper surface of the semiconductor device 11a, there are a region where the redistribution layer 22 is formed and a region where the redistribution layer 22 is not formed.

Even in the region where the redistribution layer 22 is formed, there are a region where the redistribution layer 22 is densely formed and a region where the redistribution layer is sparsely formed.

The redistribution layer 22 is formed by, for example, electrolytic plating. Therefore, if there is a density difference in density between the redistribution layers 22, a density difference in density between the lines of electric force may occur, and as a result, the height (thickness) of the redistribution layer 22 may vary depending on the location. Specifically, since the electric field concentrates on the redistribution layer 22 in the region where the density of the redistribution layer 22 is sparse, the height of the redistribution layer 22 increases (the film thickness increases). On the other hand, in the redistribution layer 22 in the region where the density of the redistribution layer 22 is dense, the electric field is dispersed, so that the height of the redistribution layer 22 decreases (the film thickness decreases).

In the redistribution layer 22 formed in the semiconductor device 11a, the non-through hole 41 is formed in the recess-protrusion formation region 23 as illustrated in FIG. 2 in the redistribution layer 22 that is formed in a sparse region and may have a large film thickness. By providing the non-through hole 41 in the redistribution layer 22 having a possibility of increasing the film thickness, an excessive material of the redistribution layer 22 can be absorbed by the non-through hole 41, and the film thickness of the redistribution layer 22 can be prevented from increasing.

FIG. 2 illustrates the case where the number of the non-through holes 41 formed in the recess-protrusion formation region 23 is one, but a plurality of the non-through holes may be formed (described later as a second embodiment). The depth and width (size) of the non-through hole 41 may be set by the degree of sparseness of the redistribution layer 22. In other words, it is configured such that the adjustment can be performed in the recess-protrusion formation region 23 such that the plating area (the region where the redistribution layer 22 including the through electrode 21 is formed) on the upper surface of the semiconductor device 11 is uniform over the entire upper surface.

In the example illustrated in FIG. 2, the plating area around the redistribution layer 22 can be adjusted by changing the number, depth, size of diameter, and the like of the non-through holes 41 provided in the recess-protrusion formation region 23. That is, the shape of the non-through hole 41 can be designed according to the degree of the density difference of the redistribution layer 22, and the variation in the height of the redistribution layer 22 can be eliminated.

For example, in a case where the degree of sparseness is high, the depth of the non-through hole 41 may be increased, or the size (diameter) of the opening may be increased. The depth of the non-through hole 41 may be provided up to a position not in contact with the wiring layer 31, in other words, up to a position not penetrating the silicon substrate 32.

Since the height of the redistribution layer 22 tends to decrease (the film thickness decreases) in the vicinity of the through electrode 21, when the non-through hole 41 is formed in the vicinity of the through electrode 21, the height of the redistribution layer 22 in the vicinity of the through electrode 21 may decrease. The position of the non-through hole 41 can be set such that the through electrode 21 and the non-through hole 41 are provided at distant positions to such an extent that there is no influence on the film thickness. For example, the through electrode 21 and the non-through hole 41 can be disposed at a distance of 200 um or more.

The depth of the non-through hole 41 and the diameter of the opening can be set to about 70% or less as compared with the depth of the through electrode 21 and the diameter of the opening. When the ratio is 70% or less, the through electrode 21 and the non-through hole 41 can be processed in the same step during manufacturing. In addition, at the time of etching back the insulating film 33, the wiring 36 under the through electrode 21 can be exposed without opening the bottom portion of the through electrode 21, and the non-through hole 41 of the recess-protrusion formation region 23 can be formed without increasing the number of processes.

Although the non-through hole 41 illustrated in FIG. 2 is a hollow in the non-through hole 41, the same material as the redistribution layer 22, for example, Cu may be embedded in the non-through hole 41 (described later as a fourth embodiment). In a case where Cu is embedded inside the non-through hole 41, since the wiring cross-sectional area increases, it is possible to reduce a resistance value, improve electro migration (EM) resistance, or improve adhesion of an interface between the redistribution layer 22 and the insulating film 33.

In this manner, the redistribution layer 22 in which the height of the redistribution layer 22 is increased (the film thickness is increased) is provided with the recess-protrusion formation region 23. In the recess-protrusion formation region 23, one or a plurality of non-penetrating vias (non-through holes 41) for adjusting the film thickness is formed. By forming the non-through hole 41 and adjusting the film thickness, it is possible to bring about a state in which there is no density difference of the redistribution layer 22, and it is possible to prevent a density difference in density of lines of electric force from occurring.

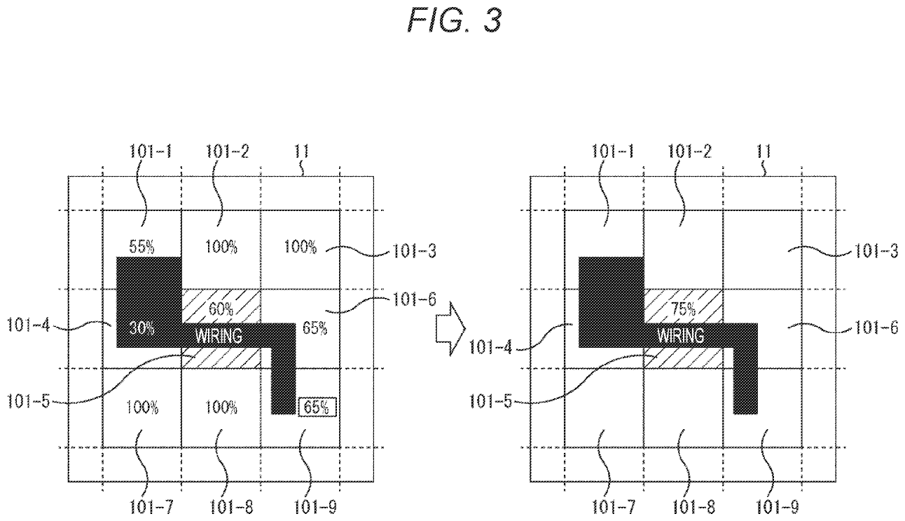

An example of a criterion for determining whether the redistribution layer 22 is a sparse region or a dense region will be described with reference to FIG. 3.

The surface of the semiconductor device 11a on which the redistribution layer 22 is formed is virtually divided into a lattice shape of a predetermined size, and the pattern writing area density in the section is calculated. The left diagram of FIG. 3 illustrates, as an example, nine sections of 3×3 in a case where the surface of the semiconductor device 11 on which the redistribution layer 22 is formed is divided into a lattice shape. The numerical values illustrated in the respective sections in the left diagram of FIG. 3 indicate the pattern writing area density.

In a case where the redistribution layer 22 is formed by plating, the pattern writing area density can be a ratio of a resist applied to a portion other than the portion where the wiring is formed. Here, a case where the pattern writing area density=the ratio of the resist will be described as an example. When the redistribution layer 22 is formed, a portion of the resist where the redistribution layer 22 is to be formed is removed, and the resist is left at other portions. It can also be said that the pattern writing area density is an area other than the region where the wiring is formed in the section. Therefore, a region where the pattern writing area density is high is a region where the ratio of the resist is high and the region where the wiring is formed is small.

The pattern writing area density of a section 101-1 is 55%, the pattern writing area density of a section 101-2 is 100%, and the pattern writing area density of a section 101-3 is 100%. The pattern writing area density of a section 101-4 is 30%, the pattern writing area density of a section 101-5 is 60%, and the pattern writing area density of a section 101-6 is 65%. The pattern writing area density of a section 101-7 is 100%, the pattern writing area density of a section 101-8 is 100%, and the pattern writing area density of a section 101-9 is 65%.

In a case where it is determined whether the section 101-5 is sparse or dense, the determination is made not only by the pattern writing area density of the section 101-5 but also by using the pattern writing area density of the section around the section 101-5. Here, an example will be described in which the average value of the pattern writing area densities in the sections 101-1 to 101-9 is calculated, and it is determined whether or not the average value is a predetermined threshold or more to determine whether or not the section is sparse.

The average value of the pattern writing area density in the section 101-5 is calculated as 75%(=(55+100+100+30+60+65+100+100+65)/9) as illustrated in the right diagram of FIG. 3. For example, in a case where the threshold is set to 70%, and it is set that it is determined to be sparse in a case where the average value is 70% or more, the section 101-5 is determined to be a sparse region.

The shape and size of the recess-protrusion formation region 23 of the redistribution layer 22 may be set by the average value of the pattern writing area density.

In a case where sparseness/denseness of a predetermined section is determined, it is possible to more accurately determine sparseness/denseness by determining the sparseness/denseness not only by a numerical value of the section but also by determining the sparseness/denseness in consideration of numerical values of surrounding sections.

FIG. 1 is referred to again. Assume a case where sparseness/denseness of a predetermined section is determined only by the pattern writing area density of the section. For example, the redistribution layers 22-1 to 22-5 illustrated in FIG. 1 are arranged at equal intervals and formed with substantially equal lengths. In the case of such redistribution layers 22-1 to 22-5, since there is a high possibility that the pattern writing area densities are the same, there is a high possibility that the same determination of sparse or dense is made.

On the other hand, as described with reference to FIG. 3, in a case where the sparseness/denseness of the predetermined section is determined, the determination is made not only by the numerical value of the section but also in consideration of the numerical values of the surrounding sections, so that, for example, it is possible to make a different determination that the redistribution layer 22-1 is sparse and the redistribution layer 22-2 is dense.

For example, in a case where attention is paid to the redistribution layer 22-2, the redistribution layer 22-1 and the redistribution layer 22-2 are arranged on both sides of the redistribution layer 22-2, respectively. Therefore, in consideration of the redistribution layer 22-2 and the surrounding situation, it is determined that the redistribution layer 22-2 is dense.

On the other hand, for example, in a case where attention is paid to the redistribution layer 22-1, the redistribution layer 22-1 has the redistribution layer 22-2 on the right side, but the redistribution layer 22 is not arranged on the left side. Therefore, in consideration of the redistribution layer 22-1 and the surrounding situation, it is determined that the redistribution layer 22-1 is sparse.

As described above, in a case where sparseness/denseness of a predetermined section is determined, it is possible to more accurately determine sparseness/denseness by determining the sparseness/denseness in consideration of the situation of the section and the surrounding sections. Using the result of the sparseness/denseness determination, to what extent the recess-protrusion formation region 23 is provided, specifically, the size, depth, and the like of the recess-protrusion formation region 23 are set.

In the example illustrated in FIG. 1, for example, in a case where the recess-protrusion formation region 23-1 of the redistribution layer 22-1 is compared with the recess-protrusion formation region 23-2 of the redistribution layer 22-2, the recess-protrusion formation region 23-1 of the redistribution layer 22-1 determined to be sparse is formed to be larger than the recess-protrusion formation region 23-2 of the redistribution layer 22-2 determined to be dense. The size and shape of the recess-protrusion formation region 23 may be set according to the degree of the average value of the pattern writing area density calculated for the redistribution layer 22.

Note that the method of determining sparseness/denseness described herein is an example, and the determination may be performed by other determination methods without limitation. Furthermore, the shape, size, and the like of the recess-protrusion formation region 23 may be set according to the determination result (numerical value).

As described above, the size, depth, and the like of the recess-protrusion formation region 23 are set such that the plating area per unit area of the upper surface of the semiconductor device 11 is uniform over the entire upper surface.

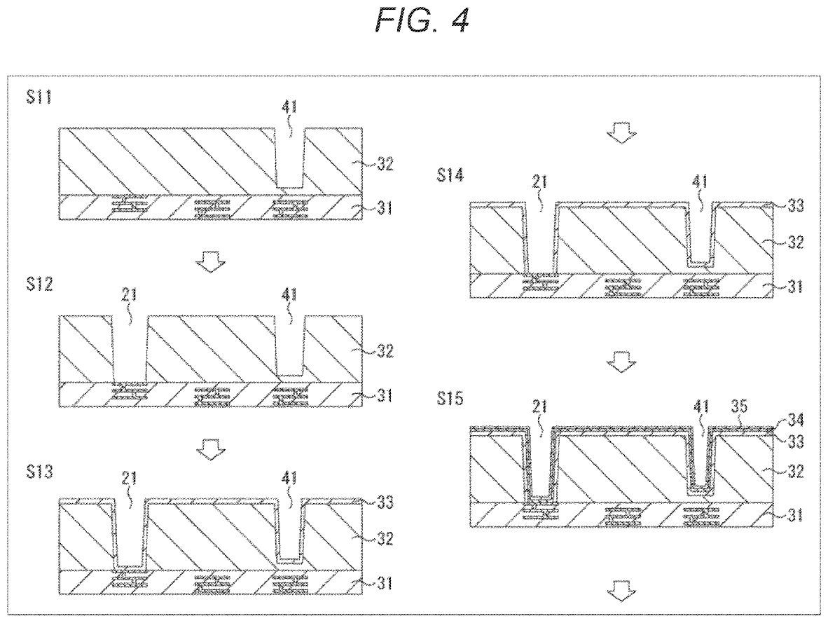

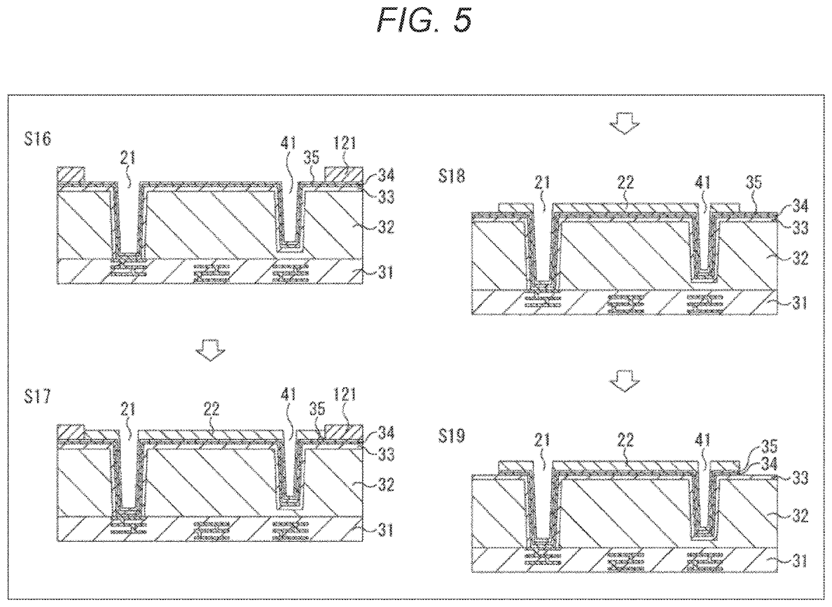

The manufacturing of the semiconductor device 11a illustrated in FIG. 2 will be described with reference to FIGS. 4 and 5.

In step S11, the non-through hole 41 is formed in the silicon substrate 32 on the wiring layer 31. In step S12, the through hole is formed at a position to be the through electrode 21. In a case where the diameter and depth of the non-through hole 41 are about 70% or less of the diameter and depth of the through electrode 21, steps S11 and S12 can be simultaneously performed, and the non-through hole 41 and the through electrode 21 (through holes to be formed) can be simultaneously formed with the same mask. The non-through hole 41 and the through electrode 21 can be formed by lithography and dry etching.

In step S13, the insulating film 33 is formed by a chemical vapor deposition (CVD) method, an atomic layer deposition (ALD) method, or the like. In step S14, the insulating film 33 is etched back by dry etching, and the wiring 36 in the wiring layer 31 connected to the through electrode 21 is exposed.

In step S14, by setting the diameter and depth of the non-through hole 41 to about 70% or less of the diameter and depth of the through electrode 21, it is possible to prevent the insulating film 33 at the bottom of the non-through hole 41 from being opened even when etching back is performed. In addition, since the coverage of the insulating film 33 is low, the insulating film 33 of the field portion (the upper portion of the through electrode 21) is formed to be thicker than the insulating film 33 of the bottom portion of the through electrode 21, so that the insulating film of the field portion does not disappear even when etching back is performed.

In step S15, the barrier metal film 34 is formed by a physical vapor deposition (PVD) method, a CVD method, an ALD method, or the like, and the seed film 35 is formed. Ta, TaN, Ti, or the like can be used for the barrier metal film 34, and Cu can be used for the seed film 35.

In step S16 (FIG. 5), a portion other than a portion where the redistribution layer 22 is to be formed by lithography is covered with a resist 121, and in step S17, a Cu film, that is, the redistribution layer 22 is formed by Cu plating by a semi-additive method. Note that, in step S16, the ratio of the region covered with the resist 121 can be used as the above-described pattern writing area density.

In step S18, the resist 121 is peeled off by wet etching, and in step S19, the seed film 35 and the barrier metal film 34 under the resist 121 are sequentially peeled off.

In such a process, the redistribution layer 22 is formed, and the recess-protrusion formation region 23 (the non-through hole 41) is formed. Note that the manufacturing process illustrated here is an example, and is not a description indicating limitation. The semiconductor device 11a as illustrated in FIG. 2 may be manufactured by other manufacturing processes.

### Second Embodiment

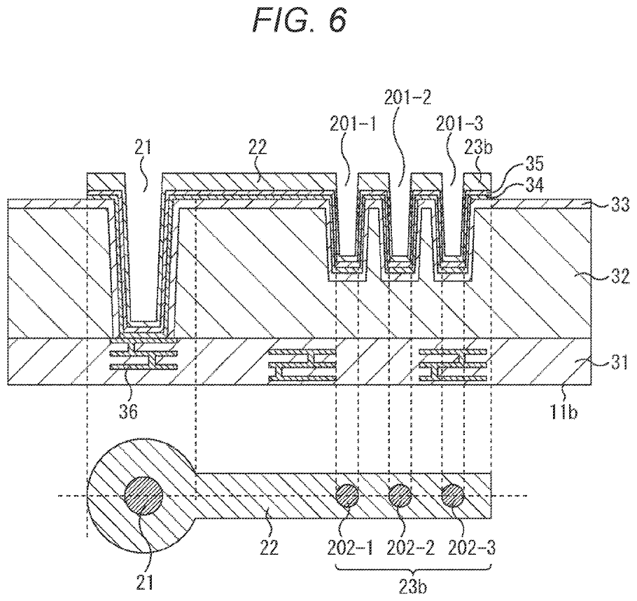

The upper part in FIG. 6 is a cross-sectional view illustrating a configuration example of a semiconductor device 11b according to a second embodiment, and the lower part in FIG. 6 is a diagram illustrating a configuration of the redistribution layer 22. Note that FIG. 6 corresponds to a cross-sectional configuration example at the line A-A′ of the semiconductor device 11a in FIG. 1, but in the following description, the through electrode 21-7, the redistribution layer 22-7, and the recess-protrusion formation region 23-7 will be described as the through electrode 21, the redistribution layer 22, and the recess-protrusion formation region 23, respectively.

In the semiconductor device 11b according to the second embodiment, similar parts to those of the semiconductor device 11a (FIG. 2) according to the first embodiment are denoted by similar reference numerals, and the description thereof will be appropriately omitted.

The semiconductor device 11b according to the second embodiment is different from the semiconductor device 11a according to the first embodiment in that a plurality of non-through holes 201-1 to 201-3 is formed in a recess-protrusion formation region 23b of the semiconductor device 11b, but the other points are similar.

The non-through holes 201-1 to 201-3 are formed in the recess-protrusion formation region 23b of the semiconductor device 11b. These non-through holes 201-1 to 201-3 are designed to have a small diameter and a shallow depth. By setting the diameter and the depth of each of the non-through holes 201-1 to 203-3 to values obtained by reducing the diameter and the depth by about 30% from the diameter and the depth of the through electrode 21, the through electrode 21 and the non-through holes 201-1 to 201-3 can be simultaneously formed with the same mask at the time of manufacturing.

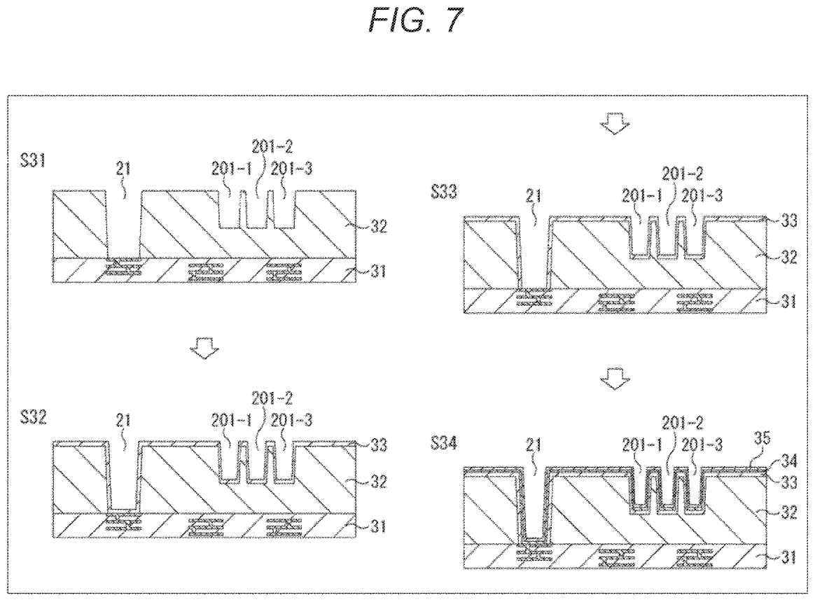

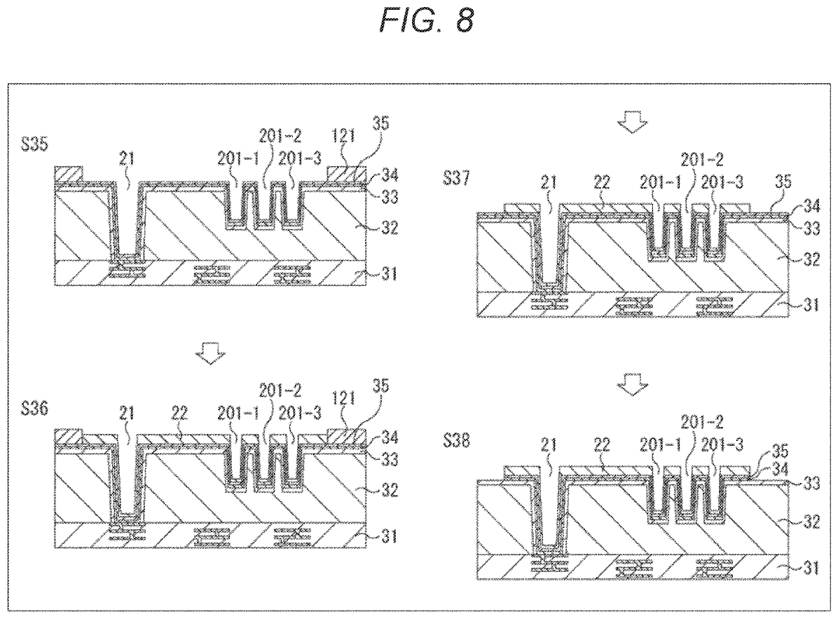

In the example illustrated in FIG. 6, three non-through holes 201-1 to 201-3 are formed, but the number is not limited to three and may be any number. The number, the size of the diameter, the depth, and the like of the non-through holes 201 formed in the recess-protrusion formation region 23b are set by the degree of sparseness of the redistribution layer 22. The manufacturing of the semiconductor device 11b illustrated in FIG. 6 will be described with reference to FIGS. 7 and 8.

In step S31, the through electrode 21 and the non-through hole 201 are formed in the silicon substrate 32 on the wiring layer 31. In a case where the diameter and depth of the non-through hole 201 are designed to be about 30% smaller than the diameter and depth of the through electrode 21, the through electrode 21 and the non-through hole 201 can be simultaneously formed with the same mask in step S31.

In step S32, the insulating film 33 is formed by a CVD method, an ALD method, or the like. In step S33, the insulating film 33 is etched back by dry etching, and the wiring 36 in the wiring layer 31 connected to the through electrode 21 is exposed. In step S34, the barrier metal film 34 is formed by a PVD method, a CVD method, an ALD method, or the like, and the seed film 35 is formed.

In step S35 (FIG. 8), a portion other than a portion where the redistribution layer 22 is to be formed by lithography is covered with the resist 121, and in step S36, a Cu film, that is, the redistribution layer 22 is formed by Cu plating by a semi-additive method. In step S37, the resist 121 is peeled off by wet etching, and in step S38, the seed film 35 and the barrier metal film 34 on the lower side of the resist 121 are sequentially peeled off.

In such a process, the redistribution layer 22 is formed, and the recess-protrusion formation region 23 (the non-through hole 201) is formed.

### Third Embodiment

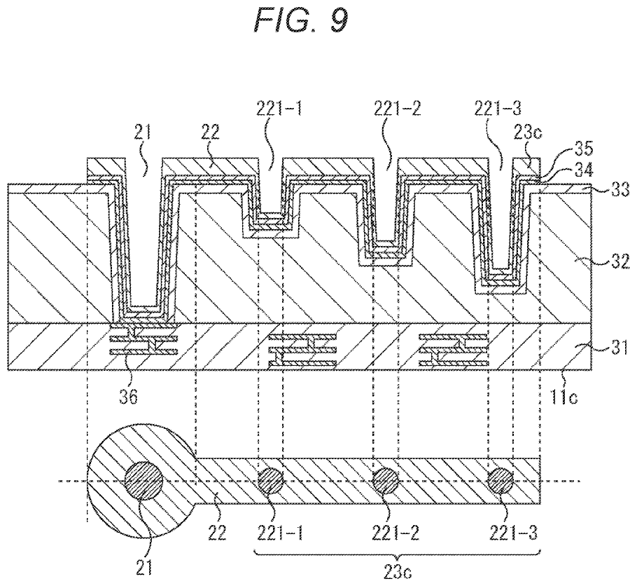

The upper part in FIG. 9 is a cross-sectional view illustrating a configuration example of a semiconductor device 11c according to a third embodiment, and the lower part in FIG. 9 is a diagram illustrating a configuration of the redistribution layer 22. In the semiconductor device 11c according to the third embodiment, similar parts to those of the semiconductor device 11a (FIG. 2) according to the first embodiment are denoted by similar reference numerals, and the description thereof will be appropriately omitted.

The semiconductor device 11c according to the third embodiment is different from the semiconductor device 11a according to the first embodiment in that a plurality of non-through holes 221-1 to 221-3 is formed in a recess-protrusion formation region 23c of the semiconductor device 11c, but the other points are similar. The non-through holes 221-1 to 221-3 are configured to have different depths. The non-through hole 221-2 is deeper than the non-through hole 221-1, and the non-through hole 221-3 is deeper than the non-through hole 221-2.

The sizes of the diameters of the non-through holes 221-1 to 222-3 are also different from each other. The diameter of the non-through hole 221-2 is larger than that of the non-through hole 221-1, and the diameter of the non-through hole 221-3 is larger than that of the non-through hole 221-2. The distances between the non-through holes 221 may be equal or different.

As described above, since the film thickness tends to be thin on the side close to the through electrode 21, the non-through hole 221 arranged on the side close to the through electrode 21 is formed small, and the non-through hole 221 arranged on the side far from the through electrode 21 is formed large.

The depth, the size of the diameter, the distance between the non-through holes 221, and the like of each of the non-through holes 221-1 to 221-3 formed in the recess-protrusion formation region 23c are set by the degree of sparseness of the redistribution layer 22.

As described above, it is also possible to adopt a configuration in which a plurality of the non-through holes 221 having different depths, sizes of diameters, and distances of the non-through holes 221-1 to 221-3 formed in the recess-protrusion formation region 23c is formed, and the film thickness of the redistribution layer 22 is adjusted. Note that only one of the depths and the sizes of the diameters of the non-through holes 221-1 to 221-3 may be different.

### Fourth Embodiment

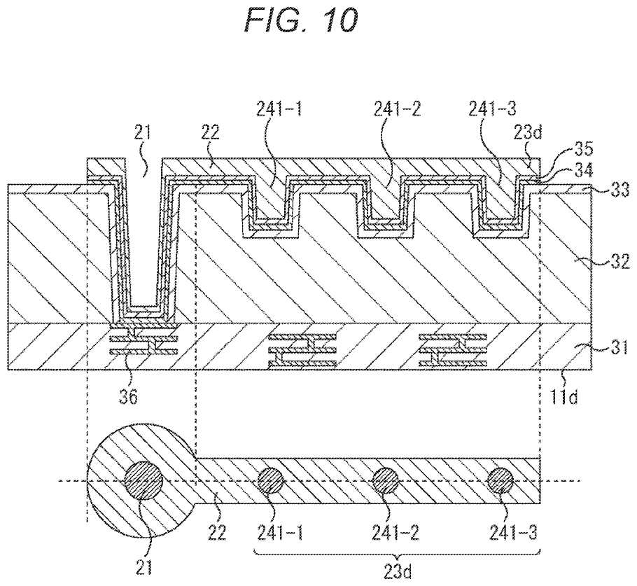

The upper part in FIG. 10 is a cross-sectional view illustrating a configuration example of a semiconductor device 11d according to a fourth embodiment, and the lower part in FIG. 10 is a diagram illustrating a configuration of the redistribution layer 22. In the semiconductor device 11d according to the fourth embodiment, similar parts to those of the semiconductor device 11a (FIG. 2) according to the first embodiment are denoted by similar reference numerals, and the description thereof will be appropriately omitted.

The semiconductor device 11d according to the fourth embodiment is different from the semiconductor device 11a according to the first embodiment in that a plurality of non-through holes 241-1 to 241-3 is formed in the recess-protrusion formation region 23d of the semiconductor device 11d, and Cu (copper) is embedded in the non-through holes 241, but the other points are similar.

The semiconductor device 11b according to the second embodiment (FIG. 6) and the fourth embodiment may be combined, and Cu may be embedded in the non-through holes 201-1 to 201-3 of the semiconductor device 11b according to the second embodiment.

The semiconductor device 11c according to the third embodiment (FIG. 9) and the fourth embodiment may be combined, and Cu may be embedded in the non-through holes 221-1 to 221-3 of the semiconductor device 11c according to the third embodiment.

In a case where Cu is embedded in the non-through hole 241 as in the non-through hole 241, since the wiring cross-sectional area increases, it is possible to reduce a resistance value, improve electro migration (EM) resistance, or improve adhesion of an interface between the redistribution layer 22 and the insulating film 33.

### Fifth Embodiment

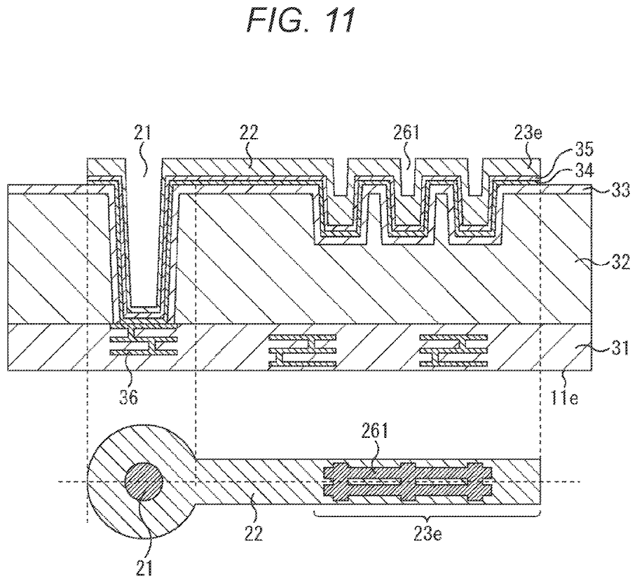

The upper part in FIG. 11 is a cross-sectional view illustrating a configuration example of a semiconductor device 11e according to a fifth embodiment, and the lower part in FIG. 11 is a diagram illustrating a configuration of the redistribution layer 22. In the semiconductor device 11e according to the fifth embodiment, similar parts to those of the semiconductor device 11a (FIG. 2) according to the first embodiment are denoted by similar reference numerals, and the description thereof will be appropriately omitted.

The semiconductor device 11e according to the fifth embodiment is different from the semiconductor device 11a according to the first embodiment in that a non-through hole 261 is formed in a lattice shape in a recess-protrusion formation region 23e of the semiconductor device 11e, but the other points are similar.

In the recess-protrusion formation region 23e of the semiconductor device 11e, as illustrated in the lower part of FIG. 11, the non-through hole 261 is formed in a lattice shape in plan view. As illustrated in the upper part of FIG. 11, in the cross-sectional view, a plurality of non-through holes 261 is formed in the recess-protrusion formation region 23e.

The lattice shape is a shape including at least one line and a line intersecting the line. The lower part of FIG. 11 illustrates an example in which a lattice shape is formed by two horizontal lines and three vertical lines perpendicularly intersecting the two horizontal lines.

The number and arrangement of lines constituting the lattice-shaped non-through holes 261, the thickness and depth of each line, and the like are set according to the degree of sparseness of the redistribution layer 22. By forming the non-through hole 261 formed in the recess-protrusion formation region 23e into a lattice shape, the plating area can be increased, and the film thickness can be configured to be more easily adjusted.

The semiconductor device 11e having the lattice-shaped non-through hole 261 can be basically manufactured in the same process as the manufacturing process of the semiconductor device 11a described with reference to FIGS. 5 and 6. By using a lattice-shaped mask as the mask for forming the non-through holes 41 in step S11, the semiconductor device 11e having the lattice-shaped non-through holes 261 can be manufactured.

### Sixth Embodiment

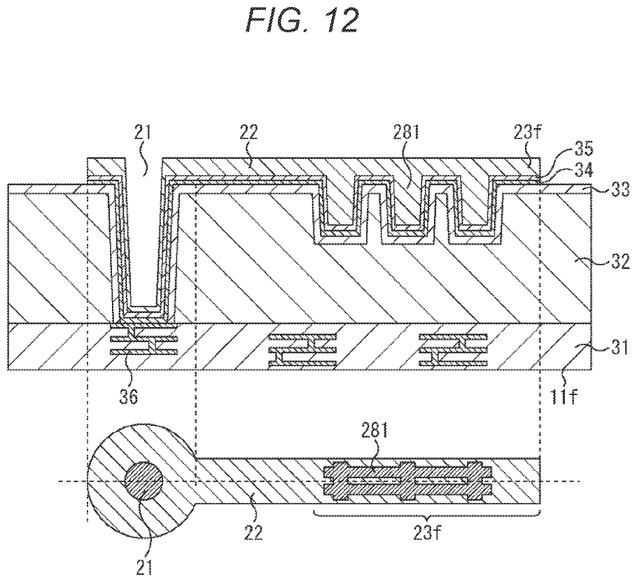

The upper part in FIG. 12 is a cross-sectional view illustrating a configuration example of a semiconductor device 11f according to a sixth embodiment, and the lower part in FIG. 12 is a diagram illustrating a configuration of the redistribution layer 22. In the semiconductor device 11f according to the sixth embodiment, similar parts to those of the semiconductor device 11e (FIG. 11) according to the fifth embodiment are denoted by similar reference numerals, and the description thereof will be appropriately omitted.

The semiconductor device 11f according to the sixth embodiment is similar to the semiconductor device 11e according to the fifth embodiment in that a lattice-shaped non-through hole 281 is formed in a recess-protrusion formation region 23f of the semiconductor device 11f. A semiconductor device 11f according to the sixth embodiment is different from the semiconductor device 11e according to the fifth embodiment in that Cu (copper) is embedded in the non-through hole 281 of the recess-protrusion formation region 23f of the semiconductor device 11f.

In a case where Cu is embedded in the non-through hole 281 as in the non-through hole 281, since the wiring cross-sectional area increases, it is possible to reduce a resistance value, improve electro migration (EM) resistance, or improve adhesion of an interface between the redistribution layer 22 and the insulating film 33.

### Seventh Embodiment

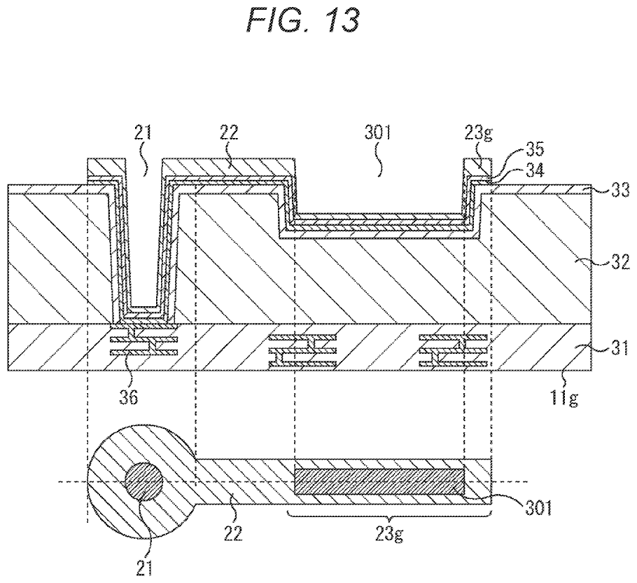

The upper part in FIG. 13 is a cross-sectional view illustrating a configuration example of a semiconductor device 11g according to a seventh embodiment, and the lower part in FIG. 13 is a diagram illustrating a configuration of the redistribution layer 22. In the semiconductor device 11g according to the seventh embodiment, similar parts to those of the semiconductor device 11a (FIG. 2) according to the first embodiment are denoted by similar reference numerals, and the description thereof will be appropriately omitted.

The semiconductor device 11g according to the seventh embodiment is different from the semiconductor device 11a according to the first embodiment in that a slit-shaped non-through hole 301 is formed in a recess-protrusion formation region 23g of the semiconductor device 11g, but the other points are similar.

As illustrated in the lower part of FIG. 13, the non-through hole 301 is formed to have a width smaller than the width of the redistribution layer 22 in plan view, and is formed in a quadrangular shape formed to have a predetermined length. As illustrated in the upper part of FIG. 13, in the cross-sectional view, the non-through hole 301 is formed to have a predetermined depth, and the depth is formed to be shallower than the depth of the through electrode 21.

The size and depth of the slit-shaped non-through hole 301 are set according to the degree of sparseness of the redistribution layer 22, and are adjusted such that the film thickness of the redistribution layer 22 is uniform. By setting the depth of the non-through hole 301 to a depth that is about 50% less than the depth of the through electrode 21, it is possible to simultaneously form the non-through hole with the same mask as the through electrode 21 at the time of manufacturing.

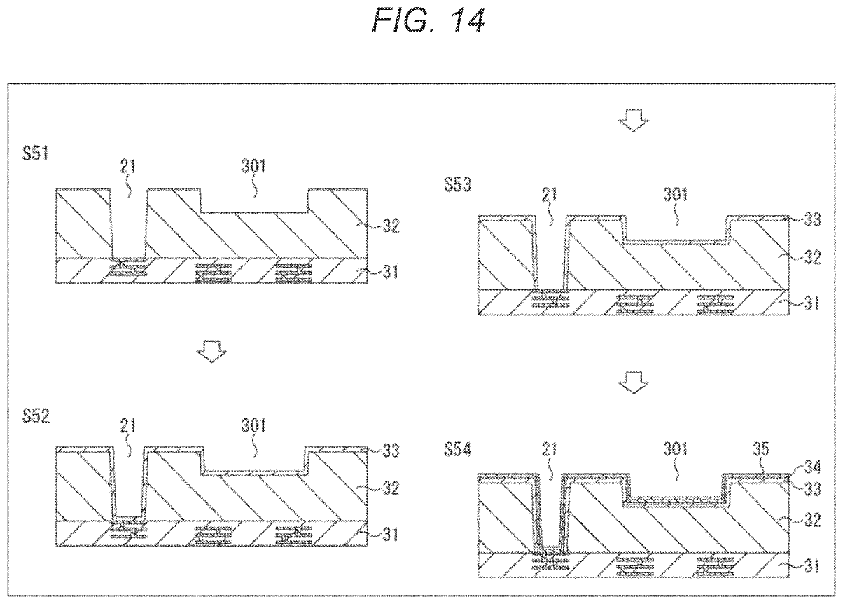

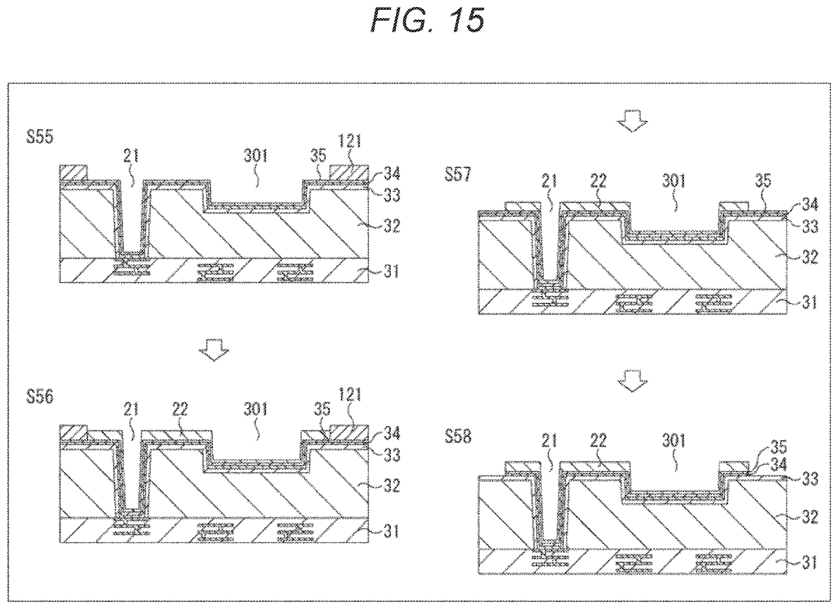

The manufacturing of the semiconductor device 11b illustrated in FIG. 13 will be described with reference to FIGS. 14 and 15.

In step S51, the through electrode 21 and the non-through hole 301 are formed in the silicon substrate 32 on the wiring layer 31. In a case where the depth of the non-through hole 301 is set to a depth that is about 50% less than the depth of the through electrode 21, the through electrode 21 and the non-through hole 301 can be simultaneously formed with the same mask in step S51.

In step S52, the insulating film 33 is formed by a CVD method, an ALD method, or the like. In step S53, the insulating film 33 is etched back by dry etching, and the wiring 36 in the wiring layer 31 connected to the through electrode 21 is exposed. In step S54, the barrier metal film 34 is formed by a PVD method, a CVD method, an ALD method, or the like, and the seed film 35 is formed.

In step S55 (FIG. 15), a portion other than a portion where the redistribution layer 22 is to be formed by lithography is covered with the resist 121, and in step S56, a Cu film, that is, the redistribution layer 22 is formed by Cu plating by a semi-additive method. In step S57, the resist 121 is peeled off by wet etching, and in step S58, the seed film 35 and the barrier metal film 34 under the resist 121 are sequentially peeled off.

In such a process, the redistribution layer 22 is formed, and the recess-protrusion formation region 23 (the non-through hole 301) is formed.

### Eighth Embodiment

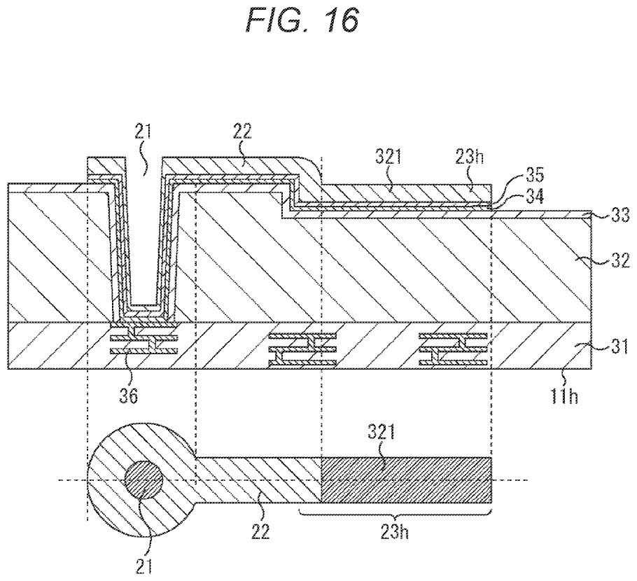

The upper part in FIG. 16 is a cross-sectional view illustrating a configuration example of a semiconductor device 11h according to an eighth embodiment, and the lower part in FIG. 16 is a diagram illustrating a configuration of the redistribution layer 22. In the semiconductor device 11h according to the eighth embodiment, similar parts to those of the semiconductor device 11a (FIG. 2) according to the first embodiment are denoted by similar reference numerals, and the description thereof will be appropriately omitted.

The redistribution layer 22 of the semiconductor device 11h according to the eighth embodiment is different from the semiconductor device 11a according to the first embodiment in that the redistribution layer is formed in a stepped shape, but the other points are similar.

In a case where the redistribution layer 22 is divided into a recess-protrusion formation region 23h and a region other than the recess-protrusion formation region 23h, there is a step between the region other than the recess-protrusion formation region 23h and the recess-protrusion formation region 23h. In a case where a region other than the recess-protrusion formation region 23h is defined as a reference height, the recess-protrusion formation region 23h (referred to as a low ground portion 321) is formed at a position lower than the reference height.

As illustrated in the lower part of FIG. 13, the low ground portion 321 is formed to have a width substantially equal to the width of the redistribution layer 22 in plan view, and is formed in a quadrangular shape formed to have a predetermined length.

As illustrated in the upper part of FIG. 13, in the cross-sectional view, the recess-protrusion formation region 23h (low ground portion 321) of the redistribution layer 22 is formed at a position lower than the redistribution layer 22 other than the recess-protrusion formation region 23h. In other words, the redistribution layer 22 is formed in a shape having a step.

In the semiconductor device 11h, the silicon substrate 32 in a region where the height of the redistribution layer is assumed to be high is formed thin in advance, so that an increase in wiring capacitance can be prevented and the height of the wiring can be reduced.

The size (area) of the recess-protrusion formation region 23h is set according to the degree of sparseness of the redistribution layer 22, and is adjusted such that the film thickness of the redistribution layer 22 is uniform. Also in this case, an increase in capacitance in the redistribution layer 22 can be suppressed.

### Ninth Embodiment

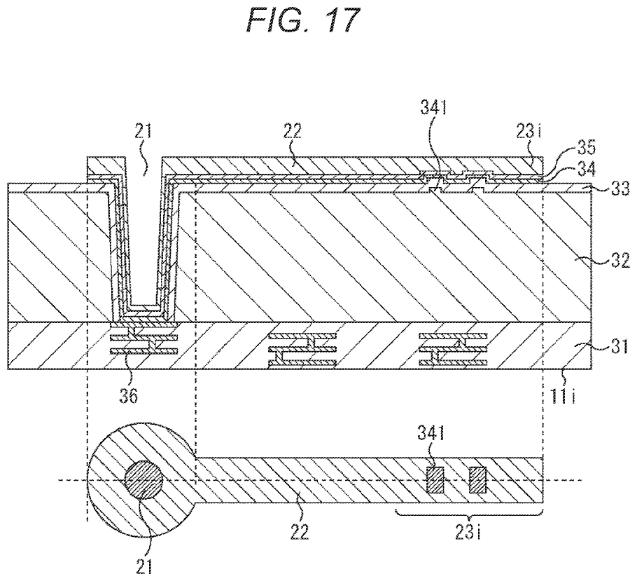

The upper part in FIG. 17 is a cross-sectional view illustrating a configuration example of a semiconductor device 11i according to a ninth embodiment, and the lower part in FIG. 17 is a diagram illustrating a configuration of the redistribution layer 22. In the semiconductor device 11i according to the ninth embodiment, similar parts to those of the semiconductor device 11a (FIG. 2) according to the first embodiment are denoted by similar reference numerals, and the description thereof will be appropriately omitted.

The semiconductor device 11i according to the ninth embodiment is different from the semiconductor device 11a according to the first embodiment in that recesses and protrusions are provided on the surface of the silicon substrate 32 in the recess-protrusion formation region 23i, and the redistribution layer 22 and the like are also formed in accordance with the recesses and protrusions, but the other points are similar.

The surface of the silicon substrate 32 on which the redistribution layer 22 is formed and in which the recess-protrusion formation region 23i is formed has an uneven shape. In the example illustrated in FIG. 17, in a case where the upper surface of the silicon substrate 32 on the lower side of the redistribution layer 22 other than the recess-protrusion formation region 23i is set as the reference surface, two protrusions 341 having a protruding shape with respect to the reference surface are formed in the recess-protrusion formation region 23i on the silicon substrate 32.

In the region where the protrusions 341 of the silicon substrate 32 are formed, the barrier metal film 34 and the seed film 35 also have a protruding shape. In a case where the recess-protrusion formation region 23i of the redistribution layer 22 formed on the seed film 35 is viewed, the silicon substrate 32 side of the recess-protrusion formation region 23i of the redistribution layer 22 has an uneven shape.

As described above, by providing the uneven shape (protrusion 341) in a part of the redistribution layer 22, it is possible to reduce variations in the height of the wiring without increasing the wiring capacitance.

The manufacturing process described with reference to FIGS. 4 and 5 can be applied to the manufacturing of the semiconductor device 11i in which the silicon substrate 32 has the protrusion 341. In step S11 (FIG. 4), the protrusion 341 is formed instead of forming the non-through hole 41. The semiconductor device 11i can be manufactured by executing the processing after step S12 on the silicon substrate 32 on which the protrusion 341 is formed.

### 10th Embodiment

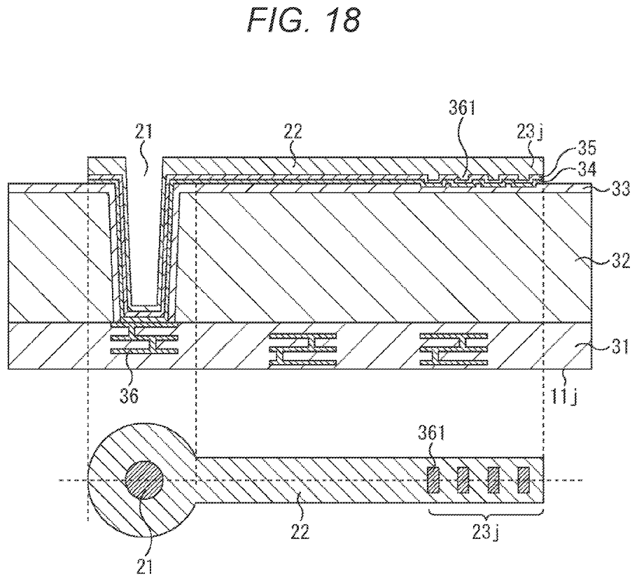

The upper part in FIG. 18 is a cross-sectional view illustrating a configuration example of a semiconductor device 11j according to a 10th embodiment, and the lower part in FIG. 18 is a diagram illustrating a configuration of the redistribution layer 22. In the semiconductor device 11j according to the 10th embodiment, similar parts to those of the semiconductor device 11i (FIG. 17) according to the ninth embodiment are denoted by similar reference numerals, and the description thereof will be appropriately omitted.

The semiconductor device 11j according to the 10th embodiment is different from the semiconductor device 11i according to the ninth embodiment in that recesses and protrusions are provided on the surface of the insulating film 33 in the recess-protrusion formation region 23j of the semiconductor device 11j, and the redistribution layer 22 and the like are also formed in accordance with the recesses and protrusions, but the other points are similar.

The surface of the insulating film 33 on which the redistribution layer 22 is formed and in which the recess-protrusion formation region 23j is formed has an uneven shape. In the example illustrated in FIG. 18, in a case where the upper surface of the insulating film 33 on the lower side of the redistribution layer 22 other than the recess-protrusion formation region 23j is set as a reference surface, four recesses 361 having a recessed shape with respect to the reference surface are formed in the insulating film 33 in the recess-protrusion formation region 23j.

In the region where the recess 361 of the insulating film 33 is formed, the barrier metal film 34 and the seed film 35 also have a recessed shape. In a case where the recess-protrusion formation region 23j of the redistribution layer 22 formed on the seed film 35 is viewed, the insulating film 33 side of the recess-protrusion formation region 23j of the redistribution layer 22 has an uneven shape.

As described above, by providing the uneven shape in a part of the redistribution layer 22, it is possible to reduce variations in the height of the wiring without increasing the wiring capacitance.

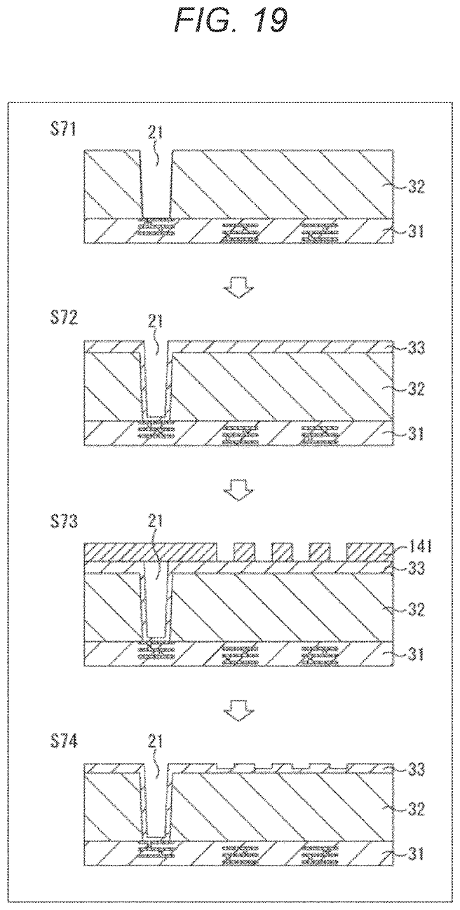

A manufacturing process of the semiconductor device 11j illustrated in FIG. 18 will be described with reference to the diagram of FIG. 19.

In step S71, the through electrode 21 is formed on the silicon substrate 32 on the wiring layer 31 by lithography and dry etching.

In step S72, the insulating film 33 is formed by a CVD method, an ALD method, or the like. Since the maximum depth of the recessed shape is determined by the thickness of the insulating film 33, the film thickness is set such that the thickness of the insulating film 33 is larger than the desired depth of the recessed shape.

In step S73, the resist 141 is formed in a portion other than a portion where the recessed shape is to be formed by lithography. In step S73, the portion of the through electrode 21 tents the resist 141, and is controlled so that the resist 141 does not enter the through electrode 21.

In step S73, light dry etching is performed using the resist 141 as a mask, and a recessed shape is formed in the insulating film 33. In step S73, if the insulating film 33 is made too thin, there is a possibility that the insulating film 33 disappears at the time of etch-back of the insulating film 33 in the subsequent step, and thus, the etching time is adjusted so that a certain film thickness remains.

In step S74, the resist 141 is peeled off. The resist 141 is peeled off to form a recessed shape on the insulating film 33. In the processes after step S74, for example, the barrier metal film 34 and the seed film 35 are formed in the same process as the processes after step S53 illustrated in FIGS. 14 and 15, and Cu plating is performed to form the redistribution layer 22.

In such a process, the redistribution layer 22 in which the insulating film 33 in the recess-protrusion formation region 23 has a recessed shape is formed.

### 11th Embodiment

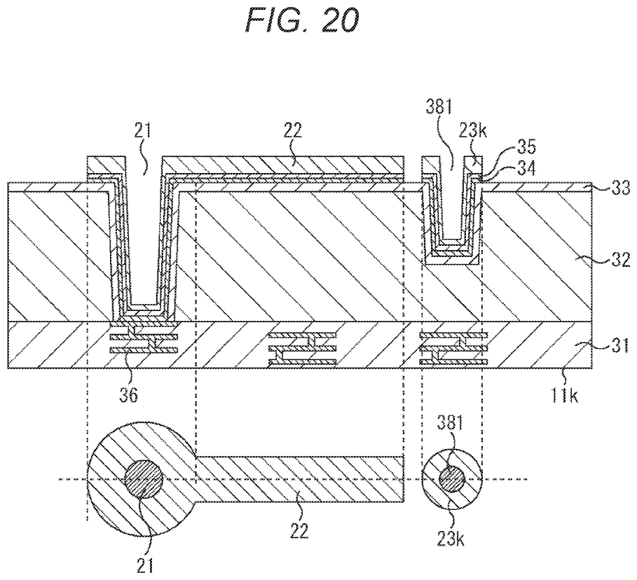

The upper part in FIG. 20 is a cross-sectional view illustrating a configuration example of a semiconductor device 11k according to an 11th embodiment, and the lower part in FIG. 20 is a diagram illustrating a configuration of the redistribution layer 22. In the semiconductor device 11k according to the 11th embodiment, similar parts to those of the semiconductor device 11a (FIG. 2) according to the first embodiment are denoted by similar reference numerals, and the description thereof will be appropriately omitted.

The semiconductor device 11k according to the 11th embodiment is different from the semiconductor device 11a according to the first embodiment in that the recess-protrusion formation region 23k is not connected to the redistribution layer 22, but the other points are similar.

A non-through hole 381 is formed in the recess-protrusion formation region 23k of the semiconductor device 11k according to the 11th embodiment illustrated in FIG. 20. The recess-protrusion formation region 23k is formed with a predetermined interval from the redistribution layer 22. The non-through hole 381 is formed in a floating state. The recess-protrusion formation region 23k is formed as a floating dummy electrode around the redistribution layer 22. Since it is a dummy electrode, the recess-protrusion formation region 23k (non-through hole 381) is formed in a state of not being connected to the wiring layer 31.

In the semiconductor device 11k, since the recess-protrusion formation region 23k is formed in a floating state, it is possible to suppress variations in the height of the redistribution layer 22 without increasing the wiring capacitance.

The manufacturing process described with reference to FIGS. 4 and 5 can be applied to the manufacturing of the semiconductor device 11k. In step S16 (FIG. 5), the resist 121 is also provided between the region to be the redistribution layer 22 and the region to be the non-through hole 381. Since Cu plating is not applied between the region to be the redistribution layer 22 provided with the resist 121 and the region to be the non-through hole 381, a state in which the redistribution layer 22 and the non-through hole 381 are not connected can be created.

The semiconductor device 11k manufactured up to a state where the redistribution layer 22 and the non-through hole 381 are not connected can be manufactured by executing the processing after step S17 on the semiconductor device 11k.

An example in which the non-through hole 381 is formed in the recess-protrusion formation region 23k illustrated in FIG. 20 is illustrated. In other words, an example in which the semiconductor device 11a (FIG. 2) according to the first embodiment and the 11th embodiment are combined has been described.

The 11th embodiment can be combined with any of the recess-protrusion formation regions 23b to 23j according to the second to 10th embodiments. That is, the redistribution layer 22 and the recess-protrusion formation regions 23a to 23j in the first to 10th embodiments may be arranged at a predetermined interval.

As described above, since the recess-protrusion formation region 23 is formed in a part of the redistribution layer 22, variations in the height of the redistribution layer 22 can be reduced without being restricted by the wiring layout. Depending on the shape of recesses and protrusions formed in the recess-protrusion formation region 23, the recess-protrusion formation region 23 can be formed in the same process using the same mask as the through electrode 21, so that the number of processes is not increased.

By forming the recess-protrusion formation region 23 only in the region where the wiring density of the redistribution layer 22 is sparse, it is possible to suppress variations in the height of the wiring.

### <Configuration of Electronic Device>

The semiconductor device 11 according to the first to 11th embodiments can be applied to an imaging element. The semiconductor device 11 described above may be used as a chip of an imaging element. The chip stacked on the semiconductor device 11 described above may be a chip on which a solid-state imaging element is formed, and the semiconductor device 11 may be a chip having a processing unit that processes a signal from the solid-state imaging element.

In a case where the semiconductor device 11 is applied to an imaging element, the imaging element can be applied to various electronic devices such as an imaging device such as a digital still camera or a digital video camera, a mobile phone having an imaging function, or another device having an imaging function, for example.

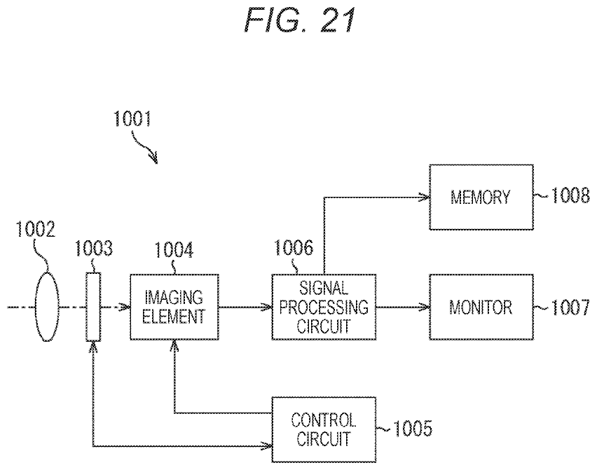

FIG. 21 is a block diagram illustrating a configuration example of an imaging device as an electronic device. An imaging device 1001 illustrated in FIG. 21 includes an optical system 1002, a shutter device 1003, an imaging element 1004, a drive circuit 1005, a signal processing circuit 1006, a monitor 1007, and a memory 1008, and can capture still images and moving images.

The optical system 1002 has one or more lenses, and guides light (incident light) from a subject to the imaging element 1004 and forms as an image on a light receiving surface of the imaging element 1004.

The shutter device 1003 is disposed between the optical system 1002 and the imaging element 1004, and controls a light irradiation period and a light shielding period with respect to the imaging element 1004 in accordance with the control of the drive circuit 1005.

The imaging element 1004 includes a package including the above-described imaging element. The imaging element 1004 accumulates signal charges for a certain period of time in accordance with light formed as an image on the light receiving surface via the optical system 1002 and the shutter device 1003. The signal charges accumulated in the imaging element 1004 are transferred in accordance with a drive signal (a timing signal) supplied from the drive circuit 1005.

The drive circuit 1005 outputs a drive signal for controlling a transfer operation of the imaging element 1004 and a shutter operation of the shutter device 1003, to drive the imaging element 1004 and the shutter device 1003.

The signal processing circuit 1006 performs various kinds of signal processing on the signal charges outputted from the imaging element 1004. The image (image data) obtained by the signal processing applied by the signal processing circuit 1006 is supplied to the monitor 1007 to be displayed or supplied to the memory 1008 to be stored (recorded).

Also in the imaging device 1001 configured as described above, an imaging element including any of the semiconductor devices 11a to 11j described above can be applied to the imaging element 1004.

### <Application Example to Endoscopic Surgery System>

The technology according to the present disclosure (present technology) can be applied to various products. For example, the technology according to the present disclosure may be applied to an endoscopic surgery system.

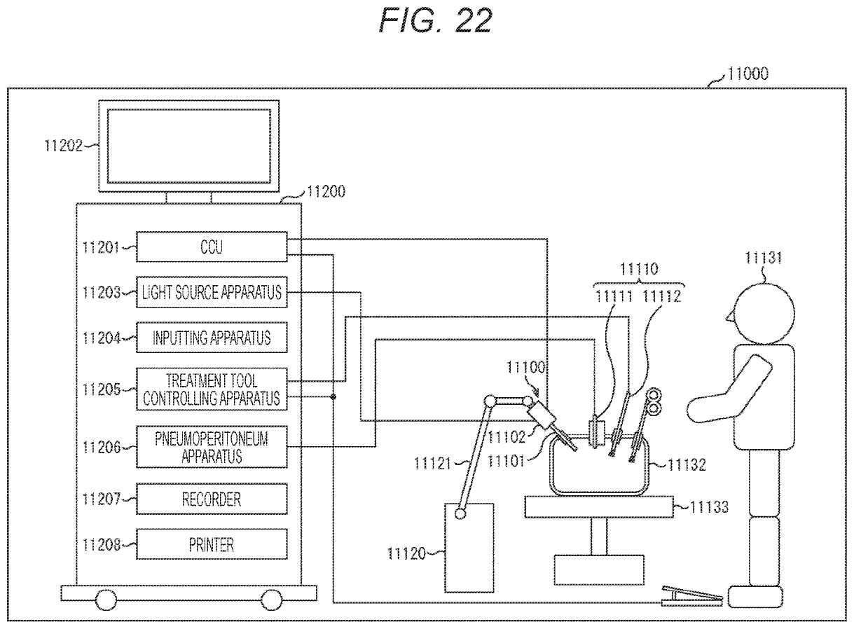

FIG. 22 is a view depicting an example of a schematic configuration of an endoscopic surgery system to which the technology according to the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit

(GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

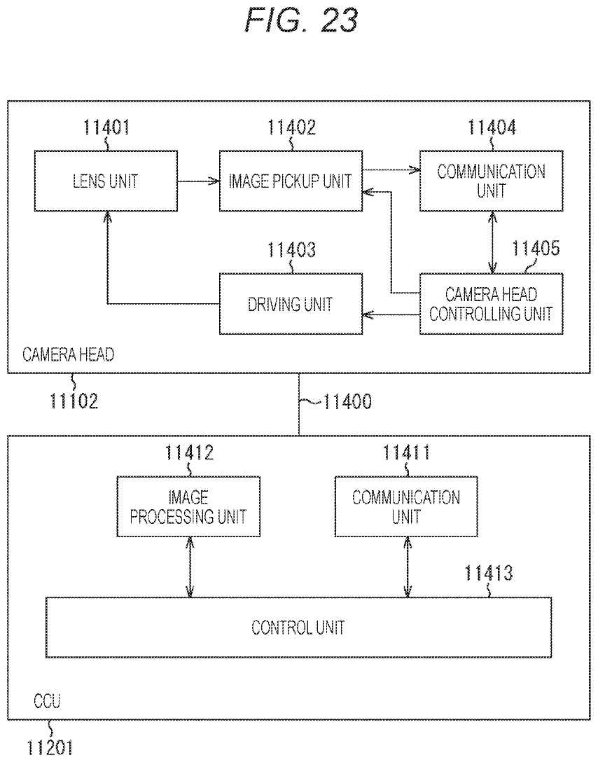

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### <Application Example to Moving Body>

The technology according to the present disclosure (present technology) can be applied to various products. For example, the technology according to the present disclosure may also be implemented as a device mounted on any type of moving body such as an automobile, an electric automobile, a hybrid electric automobile, a motorcycle, a bicycle, a personal mobility, an airplane, a drone, a ship, and a robot.

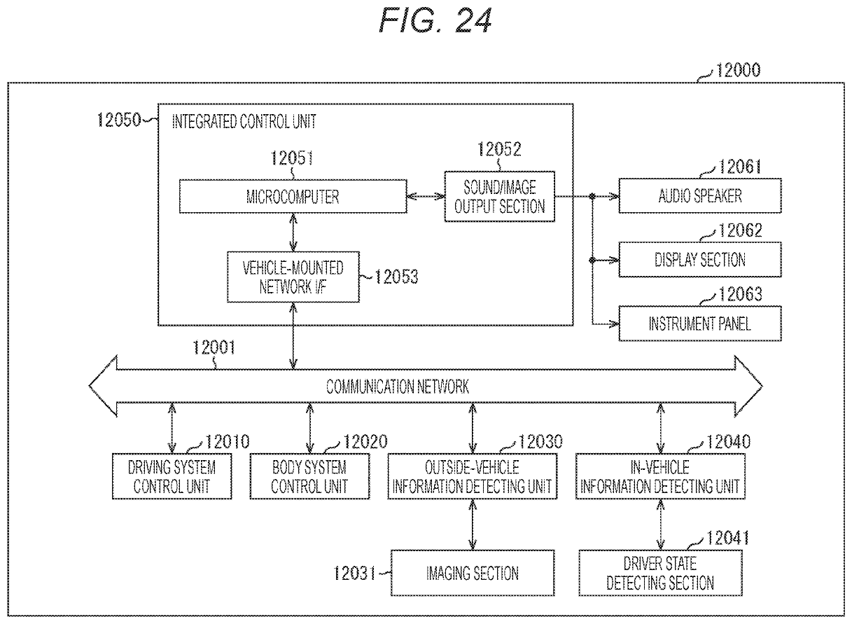

FIG. 24 is a block diagram illustrating a schematic configuration example of a vehicle control system being an example of a moving body control system to which the technology according to the present disclosure is applicable.

The vehicle control system 12000 includes a plurality of electronic control units connected to each other via a communication network 12001. In the example illustrated in FIG. 24, the vehicle control system 12000 is provided with a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 24, as the output device, an audio speaker 12061, a display section 12062, and an instrument panel 12063 are illustrated. The display section 12062 may, for example, include at least one of an on-board display and a head-up display.

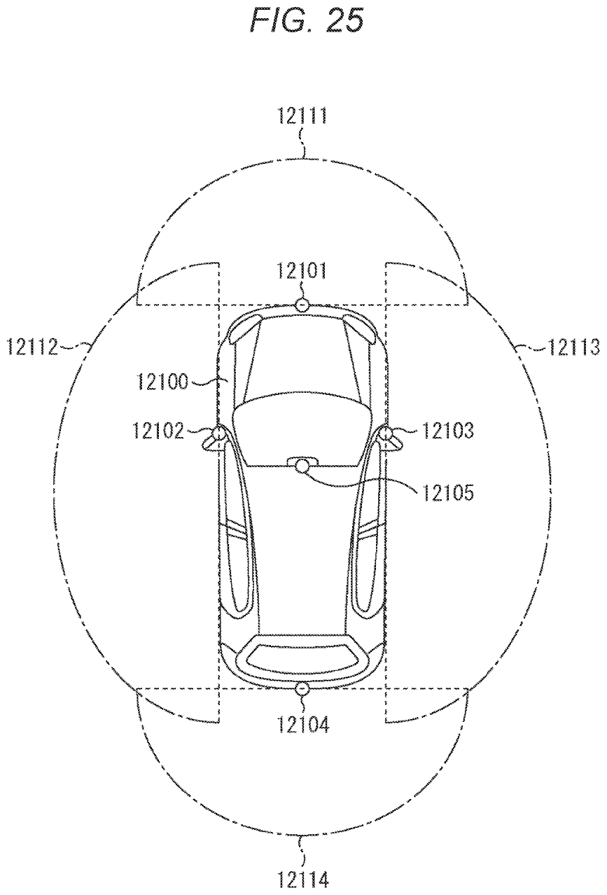

FIG. 25 is a view illustrating an example of an installation position of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, in FIG. 25, an example of imaging ranges of the imaging sections 12101 to 12104 is illustrated. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire apparatus including a plurality of apparatuses.

Note that, the effects described in the present specification are merely examples and are not limited, and there may be other effects.

Note that the embodiments of the present technology are not limited to the above-described embodiments, and various changes can be made without departing from the gist of the present technology.

Note that the present technology can adopt the following configurations.

(1)

A semiconductor device including:
a substrate;
a wiring layer on a first surface of the substrate;
a first wiring provided on a second surface opposite the first surface of the substrate; and
a through electrode that connects a second wiring in the wiring layer and the first wiring and penetrates the substrate,
in which a part of the first wiring has a region in an uneven shape.

(2)

The semiconductor device according to (1), in which the uneven shape is a non-through hole that does not penetrate the substrate.

(3)

The semiconductor device according to (2), in which a plurality of the non-through hole is provided.

(4)

The semiconductor device according to (2),
in which a plurality of the non-through hole having different depths with respect to the substrate is provided.

(5)

The semiconductor device according to (2),
in which the non-through hole has a lattice shape.

(6)

The semiconductor device according to any one of (2) to (5),
in which the non-through hole is filled with same material as the first wiring.

(7)

The semiconductor device according to (2),
in which the non-through hole has a slit shape.

(8)

The semiconductor device according to (1),
in which the first wiring is formed in a shape having a step.

(9)

The semiconductor device according to (1),
in which a region of the substrate corresponding to the region in the uneven shape of the second surface of the substrate has a protrusion in a protruding shape.

(10)

The semiconductor device according to (1), further including
an insulating film between the substrate and the first wiring,
in which a region of the insulating film corresponding to the region in the uneven shape of the second surface of the substrate has a recess in a recessed shape.

(11)

The semiconductor device according to (1),
in which the first wiring and the region in the uneven shape are arranged at a predetermined interval.

(12)

The semiconductor device according to (2),
in which a size of the non-through hole is 70% or less of a size of the through electrode.

(13)

The semiconductor device according to (7),
in which a depth of the non-through hole in the slit shape from the second surface is 50% or less of a depth of the through electrode from the second surface.

(14)

The semiconductor device according to any one of (1) to (13),
in which the uneven shape is formed in such a size that a plating area per unit area is uniform in an entire region where the first wiring is disposed.

(15)

The semiconductor device according to any one of (1) to (14),
in which the region in the uneven shape is provided on the first wiring having a large film thickness.

(16)

An imaging device including:
a first chip on which a solid-state imaging element is formed; and
a second chip that processes a signal from the first chip,
the second chip including:
a substrate;
a wiring layer on a first surface of the substrate;
a first wiring provided on a second surface opposite the first surface of the substrate; and
a through electrode that connects a second wiring in the wiring layer and the first wiring and penetrates the substrate,
in which a part of the first wiring has a region in an uneven shape.

### REFERENCE SIGNS LIST

11 Semiconductor device
21 Through electrode
22 Redistribution layer
23 Recess-protrusion formation region
31 Wiring layer
32 Silicon substrate
33 Insulating film
34 Barrier metal film
35 Seed film
36 Wiring
41 Non-through hole
101 Section
121, 141 Resist
201, 221, 241, 261, 281, 301 Non-through hole
321 Low ground portion
341 Protrusion
361 Recess
381 Non-through hole

What is claimed is:

1. A semiconductor device, comprising:
a substrate;
a wiring layer on a first surface of the substrate;
a first wiring provided on a second surface opposite the first surface of the substrate; and
a through electrode that connects a second wiring in the wiring layer and the first wiring and penetrates the substrate,
wherein a part of the first wiring has a region in an uneven shape.

2. The semiconductor device according to claim 1,
wherein the uneven shape is a non-through hole that does not penetrate the substrate.

3. The semiconductor device according to claim 2,
wherein a plurality of the non-through hole is provided.

4. The semiconductor device according to claim 2,
wherein a plurality of the non-through hole having different depths with respect to the substrate is provided.

5. The semiconductor device according to claim 2,
wherein the non-through hole has a lattice shape.

6. The semiconductor device according to claim 2,
wherein the non-through hole is filled with same material as the first wiring.

7. The semiconductor device according to claim 2,
wherein the non-through hole has a slit shape.

8. The semiconductor device according to claim 1,
wherein the first wiring is formed in a shape having a step.

9. The semiconductor device according to claim 1,
wherein a region of the substrate corresponding to the region in the uneven shape of the second surface of the substrate has a protrusion in a protruding shape.

10. The semiconductor device according to claim 1, further comprising
an insulating film between the substrate and the first wiring,
wherein a region of the insulating film corresponding to the region in the uneven shape of the second surface of the substrate has a recess in a recessed shape.

11. The semiconductor device according to claim 1,
wherein the first wiring and the region in the uneven shape are arranged at a predetermined interval.

12. The semiconductor device according to claim 2,
wherein a size of the non-through hole is 70% or less of a size of the through electrode.

13. The semiconductor device according to claim 7,
wherein a depth of the non-through hole in the slit shape from the second surface is 50% or less of a depth of the through electrode from the second surface.

14. The semiconductor device according to claim 1,
wherein the uneven shape is formed in such a size that a plating area per unit area is uniform in an entire region where the first wiring is disposed.

15. The semiconductor device according to claim 1,
wherein the region in the uneven shape is provided on the first wiring having a large film thickness.

16. An imaging device, comprising:
a first chip on which a solid-state imaging element is formed; and
a second chip that processes a signal from the first chip,
the second chip including:
a substrate;
a wiring layer on a first surface of the substrate;
a first wiring provided on a second surface opposite the first surface of the substrate; and
a through electrode that connects a second wiring in the wiring layer and the first wiring and penetrates the substrate,
wherein a part of the first wiring has a region in an uneven shape.
